(19) United States
(12) Patent Application Publication
(10) Pub. No.: US 2018/0226558 A1
(43) Pub. Date: Aug. 9, 2018

(54) THERMOELECTRIC MODULE

(71) Applicant: Mahle International GmbH, Stuttgart (DE)

(72) Inventor: Christopher Laemmle, Stuttgart (DE)

(21) Appl. No.: 15/748,185

(22) PCT Filed: Jul. 29, 2016
(86) PCT No.: PCT/EP2016/068136

§ 371 Date: Jan. 27, 2018

(30) Foreign Application Priority Data
Aug. 4, 2015 (DE) 10 2015 214 808.4
Oct. 12, 2015 (DE) 10 2015 219 738.7

(51) Int. Cl. H01L 35/32; H01L 35/18; H01L 35/34; H01L 35/30; H01L 35/10

(52) U.S. Cl. CPC H01L 35/32; H01L 35/18; H01L 35/10; H01L 35/30; H01L 35/34

(57) ABSTRACT

A thermoelectric module may include a plurality of thermoelectric elements, a first side wall connected to a plurality of first conductor bridges in a thermally conductive manner, a second side all connected to a plurality of second conductor bridges in a thermally conductive manner, and at least one liquid metal layer disposed between the first conductor bridges and an outer side of the first side wall. The at least one liquid metal layer may face away from the first conductor bridges, and at least one spacer may be arranged in the at least one liquid metal layer. The thermoelectric elements may be electrically interconnected to and extend between the first and second conductor bridges.

### CROSS-REFERENCE TO RELATED APPLICATIONS

This application claims priority to International Patent Application No. PCT/EP2016/068136, filed on Jul. 29, 2016, and German Patent Application Nos. DE 10 2015 214 808.4, filed on Aug. 4, 2015, and DE 10 2015 219 738.7, filed on Oct. 12, 2015, the contents of which are incorporated herein by reference in their entireties.

### TECHNICAL FIELD

The invention relates to a thermoelectric module comprising a plurality of thermoelectric elements.

### BACKGROUND

A thermoelectric module has a plurality of thermoelectric elements in the form of positively and negatively doped thermoelectric semiconductor materials, which are electrically interconnected, in particular in series, via a plurality of conductor bridges. The thermoelectric module has a first and a second side wall, which are in each case connected to a plurality of conductor bridges in a thermally conductive, electrically insulated and fixed manner. If a temperature difference is now applied between the first side wall and the second side wall, the thermoelectric elements generate an electrical voltage due to the Seebeck effect. As a result of the temperature difference between the first side wall and the second side wall, which is required for generating the electrical voltage, mechanical stresses caused by thermal factors are created in the thermoelectric module, which limit the maximum temperature on the warm side and the maximum temperature differences.

Thermoelectric modules can for example be used in motor vehicles for the energy recovery, In order to recover electrical energy from waste heat. Advantageously, such thermoelectric module can be integrated into heat exchangers, which couple a first fluid, which serves a heat source, to a second fluid, which serves as heat sink, to one another so as to transfer heat. Inside the respective heat exchanger, these thermoelectric modules are then disposed in a heat transfer path, along which the heat is transferred from the heat source to the heat sink.

### SUMMARY

The invention at hand is based on the object of specifying an improved or at least a different embodiment of a thermoelectric module, which is in particular characterized by reduced mechanical stresses in the module, which are caused by thermal factors, and preferably by an expanded usable temperature range.

According to the invention, this object is solved by means of the subject matter of the independent claim. Advantageous embodiments are the subject matter of the dependent subclaims.

The invention is based on the general idea of providing at least one liquid metal layer in a heat-transferring coupling path, which leads from at least one of the two side walls to the assigned conductor bridges. The mechanical fixation between the respective side wall and the corresponding conductor bridges is eliminated hereby in this heat-transferring coupling path, while the heat transfer is maintained. Such a liquid metal layer can be embodied so as to have excellent thermal conductivity and can simultaneously serve as a type of sliding film, so that mechanical stresses caused by the different thermal expansion of the first side wall and of the second side wall appear. It is advantageous that the thermoelectric module has at least such a liquid metal layer, which is disposed between the first conductor bridges and an outer side of the first side wall facing away from the first conductor bridges. The first conductor bridges are thus only thermally contacted with the first side wall, while no mechanical fixation is at hand, so that a relative movement of the first conductor bridges to the first side wall is possible. The different thermal expansions of the first side wall and of the second side wall, which are at different temperature levels during operation, can thus be compensated. Higher temperatures and also higher temperature differences between the first side wall and the second side wall can thus be used, so that the efficiency and the power density of the thermoelectric module can be improved.

In the description and the enclosed claims, a liquid metal layer is understood to be a layer, which has a metal or a metal alloy, which is liquid at least at an operating temperature. The material of the liquid metal layer can thus be solid in particular at room temperature. On principle, melting temperatures of maximally 350° C. can already be realized thereby, depending on the field of application of the thermoelectric module. Typical liquid metals can be metal-ceramic dispersions. Due to the higher thermal conductivity, essentially pure metals or metal alloys, respectively, are preferably used in thermoelectric modules. The wording “essentially pure” thereby suggests that an absolute purity cannot be attained due to the production and that, due to the production, a negligible portion of non-metallic contaminations can always be contained in such a “pure” metal alloy. Such metals or metal alloys preferably have a melting point of between 50 and 250° C. Such alloys can include for example gallium, bismuth, indium, copper, silver or tin. For example, an alloy of 32.5% of bismuth, 16.5% of tin and 51% of indium is known as Field's metal and has a melting point of approx. 62° C. A further alloy is for example 58.0% of bismuth, 42.0% of tin and has a melting point at 138° C. Other such alloys are also possible.

In the description and the enclosed claims, an operating temperature is understood to be the temperature during the operation of the thermoelectric module. Due to the fact that different temperatures typically apply on the first side and the second side of the thermoelectric module during operation, a temperature gradient runs in the thermoelectric module. The operating temperature is thus a function of the position in the thermoelectric module. For example, the operating temperature of a liquid metal layer in the vicinity of one of the side walls, which is heated during operation, is higher than the temperature of a liquid metal layer in the vicinity of the other side, which is cooled during operation.

The invention moreover proposes to dispose at least one spacer element in at least one such liquid metal layer. A provided or predetermined minimum layer thickness, respectively, can be ensured hereby in the liquid metal layer, even if the two side walls are pushed towards one another during the operation of the thermoelectric module. The latter is in particular the case, when a pretensioned abutment of the respective side wall with a wall of the heat source or the heat sink, respectively, takes place for improving the contacting and thus for the improved heat transfer. For example, said side wall can be pushed against a pipe, in which a fluid is guided, which supplies or discharges heat, respectively. Without such a spacer element, there is the risk that the liquid metal layer, which is liquid during operation, is displaced strongly and, in the extreme case, even completely, whereby it cannot fulfill its function or only to a limited extent. The respective spacer element thus improves the mode of operation of the at thermoelectric module, which is equipped with at least one such liquid metal layer. Such a spacer element preferably consists of a metal or of a metal alloy, respectively, or of a ceramic, e.g. of a glass, and has a higher melting point than the liquid metal layer. The melting point of the respective spacer element is preferably (clearly) above the operating temperatures of the thermoelectric module.

An embodiment, in the case of which a plurality of such spacer elements are disposed in the respective liquid metal layer, is particularly advantageous. During operation, a wide support can be created to ensure a desired liquid metal layer thickness. The spacer elements can thereby advantageously be disposed so as to be spaced apart from one another.

In the case of another embodiment, provision can be made for the respective spacer element to be separate with respect to the respective first conductor bridge, so that it is movable with respect to the first conductor bridges. In the alternative, provision can be made for the respective spacer element to be separate with respect to the first side wall, so that it is movable with respect to the first side wall. The respective spacer element, however, is preferably separate with respect to the first conductor bridges as well as with respect to the first side wall, so that it is movable with respect to the first conductor bridges as well as with respect to the first side wall.

An embodiment, in the case of which the respective spacer element is embodied as rolling body, is particularly advantageous. The spacer element can hereby follow the movements between the first side wall and the first conductor bridges with particularly little friction. The respective rolling body can advantageously be embodied cylindrically or spherically.

Another advantageous embodiment provides for the liquid metal layer to be in contact with an inner fixed boundary wall on a side facing the respective first conductor bridge, wherein the respective spacer element directly touches this inner boundary wall. In addition or in the alternative, provision can be made for the liquid metal layer to be in contact with an outer fixed boundary wall on a side facing the first side wall, wherein the respective spacer element directly touches this outer boundary wall. The inner and outer boundary wall are mechanically uncoupled from one another by means of the liquid metal layer and are thermally coupled to one another. The respective boundary wall can thereby be formed directly by an area of the respective side wall or of the respective conductor bridge, respectively. However, further layers are preferably used in such a thermoelectric module, e.g. for electrically insulating the conductor bridges against the side walls. Provision can likewise be made for metalized surfaces in order to improve an electrical and/or thermal coupling. At some points, metalized surfaces can be used to improve or to provide for mechanical connections, e.g. solder connections. Different embodiments of these boundary walls will be described in more detail below. They can in each case be recognized in that they are in direct contact with the liquid metal layer.

A favorable option provides for the first side of the thermoelectric module to be a cold side and for the second side of the thermoelectric module to be a warm side. The liquid metal layer is thus located on the colder side of the thermoelectric module. A melting point of the material of the liquid metal layer should thus be below 80° C.

A further favorable option provides for the first side of the thermoelectric module to be a warm side and for the second side of the thermoelectric module to be a cold side. The liquid metal layer is thus located on the warmer side of the thermoelectric module. A melting point of the liquid metal layer should thus be below 250° C., preferably below 150° C.

A particularly favorable option provides for the thermoelectric module to have an electrical insulating layer, which is disposed between the first conductor bridges and the first side wall and for at least one liquid metal layer to be disposed between the first conductor bridges and the electrical insulating layer. The first conductor bridges and thus the thermoelectric elements are thus mechanically uncoupled from the electrical insulating layer. Thermally induced mechanical stresses in the thermoelectric elements can be reduced in this way.

A further particularly favorable option provides for the at least one liquid metal layer to be disposed between the electrical insulating layer and the first side wall. The electrical insulating layer is mechanically uncoupled from the first side wall in this way. Thermally induced mechanical stresses can thus be reduced.

An advantageous solution provides for the at least one liquid metal layer to the conductor bridges to be electrically insulated. The risk of electrical short-circuits, which could be caused by the liquid metal layer, can be reduced in this way.

A further advantageous solution provides for the electrically insulating layer to be formed by a structured ceramic body and on a side, which faces the conductor bridges, for the structured ceramic body to have webs, which separates the areas assigned to the individual conductor bridges from one another. The structuring of the ceramic body and thus of the electrical insulating layer facilitates the assembly of the thermoelectric module and increases the stability of the thermoelectric module.

A particularly advantageous solution provides for the structured ceramic body to have a plurality of metalized surfaces and for the metalized surfaces to be interrupted by the webs on the side, which faces the conductor bridges. The metalized surfaces improve the contact between the ceramic body and metals. This can be advantageous for example in response to soldering. The contact of a liquid metal layer to the ceramic body is further also improved by the metalized surfaces.

In the description and the enclosed claims, a metalized surface is understood to be a surface, to which a metal layer is applied. This can for example take place by annealing a metallization paste. Such metallization pastes can for example have copper, silver or tungsten. The annealed metallization paste can additionally be coated with nickel and/or silver.

A further particularly advantageous solution provides for a plurality of liquid metal layers to be disposed between the metalized surfaces and the conductor bridges. Provision is preferably made for a liquid metal layer for each conductor bridge. The liquid metal layer can thus establish a thermal contact between the conductor bridges and the electrically insulating layer, wherein the conductor bridges are mechanically uncoupled from the electrically insulating layer.

A favorable alternative provides for a liquid metal layer to be disposed between each pair of metalized surface and conductor bridge. The temperature of all conductor bridges can thus be controlled, so that an optimal heat transfer from the first conductor bridges to the first side wall is thus made possible.

A further favorable alternative provides for the liquid metal layer to be in contact with at least one of the metalized surfaces in each case. The thermal contact to the insulating layer is thus established as well.

A particularly favorable alternative provides for the structured ceramic body to have a cohesive metalized surface on a side, which faces the first side wall. A contact to a liquid metal layer, which runs between the electrical insulating layer and the first side wall, can thus be improved. A thermal contact between the first side wall and the electrical insulating layer can thus be improved.

A further particularly favorable alternative provides for a liquid metal layer to abut on the cohesive metalized surface. The thermal contact between the structured ceramic body, thus the electrical insulating layer and the liquid metal layer, is thus improved. The thermal contact from the side wall to the electrical insulating layer is thus also improved, whereby the thermal contact between the first side wall and the first conductor bridges is improved as well.

An advantageous option provides for the electrical insulating layer to be formed by a plurality of ceramic elements and for the first conductor bridges to be formed by metalized surfaces on the ceramic elements. On the one hand, the conductor bridges can be embodied to be highly compact in this way. On the other hand, a very good thermal contact is established between the conductor bridges and the ceramic elements, so that the thermal contact as a whole from the conductor bridges to the first side wall is improved.

The metalized surfaces, which form the conductor bridges, preferably have a thickness of between 150 μm and 300 μm. Such a thickness is sufficient to provide a sufficient electrical conductivity between the thermoelectric elements, which are connected by the first conductor bridges.

A further advantageous option provides for the first side wall to have a plurality of metalized surfaces, for a liquid metal layer to abut on the metalized surfaces of the first side wall in each case, for the ceramic elements to have metalized surfaces on the side, which faces away from the conductor bridges, and for the liquid metal layers to abut on a metalized surface of the ceramic elements in each case. The liquid metal layers thus in each case abut on a metalized surface of the first side wall and on a metalized surface of a ceramic element, so that the liquid metal layers create a thermal connection between the ceramic elements and the first side wall. At the same time, the ceramic elements and the first side wall remain mechanically uncoupled from one another, so that a thermal voltage compensation is attained.

A particularly advantageous option provides for the first side wall to be embodied to be double-walled and for the first side wall to have an inner wall and an outer wall and for a liquid metal layer to be disposed between the inner wall and the outer wall. The mechanical uncoupling between the inner wall and the outer wall takes place in this way. At the same time, the thermal conductivity between the inner wall to the outer wall is maintained, so that heat can still be guided from or to the first conductor bridges.

A favorable solution provides for the electrical insulating layer to be applied to a side of the inner wall, which faces the conductor bridges. The electrical insulating layer can thus be embodied to be particularly thin, because it does not need to be mechanically supporting itself. A good heat contact across the electrical insulating layer can thus be maintained.

A further favorable solution provides for the electrical insulating layer to be formed by annealing a dielectric onto the inner wall. This is a simple option for attaining a thin electrical insulating layer.

A particularly favorable solution provides for the electrical insulating layer to be formed by thermal spraying of a ceramic onto the inner wall. A reliable thin ceramic layer can be formed in this manner. A good electrical insulation can thus be attained with a simultaneous good thermal heat conduction.

A further particularly favorable solution provides for the electrical insulating layer to be formed by a ceramic body, which is soldered onto the inner wall. This provides for a robust connection between the electrical insulating layer and the inner wall.

An advantageous alternative provides for the electrical insulating layer to be applied to the conductor bridges. A particularly thin electrical insulating layer can thus be attained, because the latter itself does not need to be weight-bearing. A sufficient electrical insulation and simultaneously a high thermal heat conductivity of the electrical insulating layer can be attained thereby.

The conductor bridges of five sides are preferably provided with the electrical insulating layer. Only the side, on which the conductor bridges are connected to the thermoelectric elements, is not provided with the electrical insulating layer. The electrical insulating layer for example can be applied to the conductor bridges by means of an immersion bath or can be sprayed onto the conductor bridges by means of spraying or can be imprinted onto the conductor bridges.

A further advantageous alternative provides for the first side wall to have a plurality of metalized surfaces, for a liquid metal layer to abut on the metalized surfaces of the first side wall in each case, for the conductor bridges to have a metalized surface on the electrical insulating layer in each case, and for the liquid metal layers to abut on a metalized surface of the insulating layer in each case. A thermal contact can thus be attained between the electrical insulating layer and the first side wall, so that a thermal contact between the first side wall and the first conductor bridges is established as well. At the same time, the first conductor bridges are mechanically uncoupled from the first side wall, so that thermal stresses are reduced.

Another advantageous embodiment provides a module housing, which surrounds a module interior, wherein the thermoelectric elements and the conductor bridges are disposed in this module interior. The first side wall forms a first side of the module housing, which is provided for contacting a heat source (or heat sink), while the second side wall forms a second side of the module housing, which is provided for contacting a heat sink (or heat source).

Lastly, the invention at hand also relates to a heat exchanger, in which at least one thermoelectric module of the above-described type is integrated. In the heat exchanger, a first fluid, which serves as heat source, and a second fluid, which serves as heat source, are coupled so as to transfer heat. The integration of the respective thermoelectric module thereby takes place such that the one side wall of the thermoelectric module is connected to the heat source so as to transfer heat, while the other side wall is connected to the heat sink.

Further important features and advantages of the invention follow from the subclaims, from the drawings, and from the corresponding figure description by means of the drawings.

It goes without saying that the above-mentioned features and the features, which will be described below, cannot only be used in the respective specified combination, but also in other combinations or alone, without leaving the scope of the invention at hand.

Preferred exemplary embodiments of the invention are illustrated in the drawings and will be described in more detail in the description below, whereby identical reference numerals refer to identical or similar or functionally identical components.

### BRIEF DESCRIPTION OF THE DRAWINGS

In each case schematically,

FIG. 1 shows a sectional illustration through a thermoelectric module according to a first embodiment,

FIG. 2 shows a sectional illustration through a thermoelectric module according to a second embodiment,

FIG. 3 shows a sectional illustration through a thermoelectric module according to a third embodiment, and

FIG. 4 shows a sectional illustration through a thermoelectric module according to a fourth embodiment,

### DETAILED DESCRIPTION

A thermoelectric module 10 illustrated in FIGS. 1 to 4 is used to create electrical energy from heat energy. For example, the thermoelectric module 10 can be used in response to the residual heat use in the exhaust tract of a motor vehicle. The thermoelectric module 10 has a module housing 12, which encloses a module interior 14. A plurality of thermoelectric elements 16, which are electrically connected by means of a plurality of conductor bridges 18, are disposed in the module interior 14. The thermoelectric elements 16 are preferably electrically connected in series by means of the conductor bridges 18. On a first side 20, the module housing 12 has a first side wall 22, which is connected to a plurality of first conductor bridges 24 so as to conduct heat. On a second side 26, the module housing 12 further has a second side wall 28, which is connected to a plurality of second conductor bridges 30 so as to conduct heat, whereby the thermoelectric elements 16 extend between the first conductor bridges 24 and the second conductor bridges 30. The conductor bridges 18 are in each case connected to the respective side walls 22, 28 via an electrical insulating layer 32 on the first side 20 as well as on the second side 26. The conductor bridges 18 are thus electrically separated from the side walls 22, 28.

The first conductor bridges 24 are connected to these thermoelectric elements 16 in an electrically conductive manner. Such an electrically conductive connection 33 can for example be established by soldering or silver sintering. In the case of a solder connection, a solder is preferably used, which has a melting point of above 120° C., for example a silver copper connection. The conductor bridges 18 preferably have copper, nickel or iron. To improve the connection, the conductor bridges 18 can have a primer, for example titanium, silver, nickel or copper. The conductor bridges 18 can furthermore have a barrier layer, for example nickel.

A first electrical insulating layer 34 is disposed between the first conductor bridges 24 and the first side wall 22. The first conductor bridges 24 are in each case in contact with the first electrical insulating layer 34 via a liquid metal layer 36.

The first conductor bridges 24 and the first electrical insulating layer 34 in each case preferably have metalized surfaces 38. The metalized surfaces 38 improved the wetting with the liquid metal of the liquid metal layer 36. The metalized surfaces 38 can for example be produced by annealing a metallization paste. Such metallization pastes can for example have copper, silver or tungsten. The thickness of the metallization layer is preferably between 20 μm and 300 μm. The layers formed by means of the metallization pastes are preferably additionally coated with nickel and/or silver.

The liquid metal layers 36 have a metal or a metal alloy, which is liquid at an operating temperature of the thermoelectric module 10. Due to the fact that a temperature gradient is present in the thermoelectric module 10 during the operation, the operating temperature is a function of the position of the respective element in the thermoelectric module 10. If the liquid metal layer 36 is for example located at a heated first side 20 of the thermoelectric module 10, a higher melting point can be sufficient, than if the liquid metal layer 36 were located at a cooled side of the thermoelectric module 10. Metals or metal alloys with a melting point of between 50° C. and 250° C. are preferably used. Such metal alloys are, for example, gallium, bismuth, indium, copper, silver and/or stannous alloys.

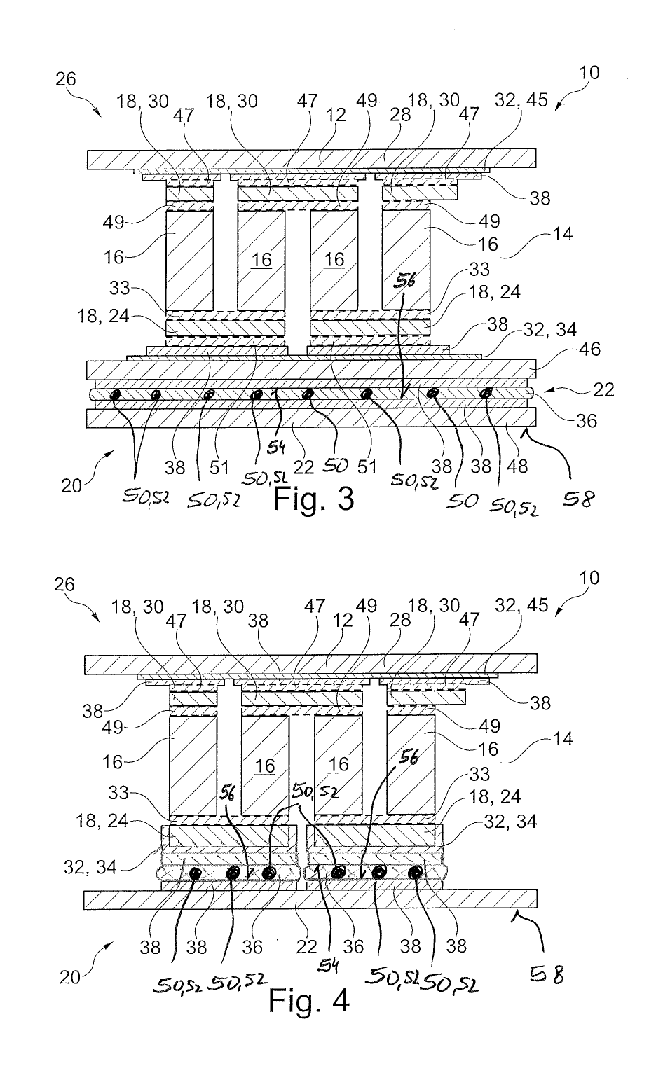

As can be gathered from the examples of FIGS. 1 to 4, the respective liquid metal layer 36 is in each case disposed between an outer side 58 of the first side wall 22, which faces away from the first conductor bridges 24. Embodiments, in the case of which exactly such a liquid metal layer 36 is provided, are shown, e.g. in FIG. 3, and embodiments, in the case of which a plurality of such liquid metal layers 36 are provided, e.g. in FIGS. 1, 2 and 4. In all embodiments, at least one spacer element 50 is disposed in at least one of these liquid metal layers 36. At least one such spacer element 50 is thereby preferably disposed in each such liquid metal layer 36. A plurality of such spacer elements 50 are advantageously disposed in the respective liquid metal layer 36. An arrangement is thereby shown, in which the individual spacer elements 50 are spaced apart from one another. It is also conceivable, however, that at least two such spacer elements 50 touch one another. The spacer elements 50 are further preferably embodied as separate components with regard to the respective first conductor bridge 24 and with regard to the first side wall 22. Provision is further made for the respective spacer element 50 to be embodied as rolling body 52. In the examples, the respective rolling body 52 is embodied cylindrically or spherically. An embodiment comprising spherical rolling bodies 52 or spacer elements 50, e.g. of metal or ceramic, in particular of glass, is preferred.

Provision is further made for the respective liquid metal layer 36 to be in contact with an inner boundary wall 54 on a side facing the respective first conductor bridge 24 and for the liquid metal layer 36 to be in contact with an outer boundary wall 56 on a side facing the first side wall 22. The respective spacer element 50 now preferably in each case touches this inner boundary wall 54 and this outer boundary wall 56 directly, so that it can roll therealong with little friction in response to relative movements between the first side wall 22 and the first conductor bridges 24.

In the embodiment shown in FIG. 1, the first electrical insulating layer 34 is formed by a ceramic body 40, which as a plurality of webs 42. The webs 42 divide the ceramic body 40 into a plurality of areas, which are in each case assigned to a first conductor bridge 24. The first conductor bridges 24 are thermally connected to the areas assigned thereto via the liquid metal layers 36.

The webs 42 separate the metalized surfaces 38 from one another on the ceramic body 40. The webs 42 furthermore separate the liquid metal layers 36 from one another, so that no electrical contact is present between the liquid metal layers 36.

On a side facing the first side wall 22, the ceramic body 40 furthermore also has a metalized surface 38, which improves the contact to a further liquid metal layer 36, which is disposed between the first electrical insulating layer 34 and the first side wall 22 and which establishes a thermal contact between these two.

To improve the wetting of the first side wall 22 with the liquid metal layer 36, the first side wall 22 can also be provided with a metalized surface 38.

By means of this arrangement, the first conductor bridges and thus the thermoelectric elements 16 to the first electrical insulating layer 34 are mechanically uncoupled, so that thermally induced mechanical stresses can be compensated. The first electrical insulating layer 34 is furthermore also mechanically uncoupled from the first side wall 22, so that the thermally induced mechanical stresses can also be reduced here. As a whole, such a setup allows for a higher operating temperature of the thermoelectric module 10, whereby a significantly improved efficiency can be attained.

On the second side 26 of the thermoelectric module 10, the second side wall 28 is provided with a second electrical insulating layer 45. This second electrical insulating layer 45 can for example be produced by annealing a dielectric or by thermally spraying a ceramic layer or by soldering a ceramic body. For example, Al₂O₃, AIN or Si₃N₄ ceramics can be used.

The second conductor bridges 30 are connected to the second electrical insulating layer 45. Such an electrically conductive connection 47 can preferably be a solder connection. For example, a soft solder comprising a melting point of above 120° C., such as tin for example, can be used. A hard solder, for example a silver copper alloy or an active solder, for example a silver copper titanium alloy, is likewise possible. In the alternative or in addition thereto, the connection 47 between the second conductor bridges 30 and the second electrical insulating layer 45 can be established by silver sintering.

To improve the wetting of the second electrical insulating layer 45, it can also be provided with a metalized surface 38.

The second conductor bridges 30 are electrically connected to the thermoelectric elements 16. Such a connection 49 could for example be a solder connection. For example a soft solder with a melting point of above 120° C., a hard solder, for example a silver copper alloy, can be used as solder. In the alternative or in addition thereto, the second conductor bridges 30 can be connected to the thermoelectric elements 16 by means of a silver sintering.

In the case of this described alternative, the first side 20 of the thermoelectric module 10 is used as hot side and the second side 26 of the thermoelectric module 10 is used as cold side. It goes without saying that a complementary use is possible a well. However, the solder connections on the second side 26, which is then the hot side, should then not be created by means of a soft solder. In return, the solder connections on the first side 20, which is then the cold side, can also be formed by means of a soft solder.

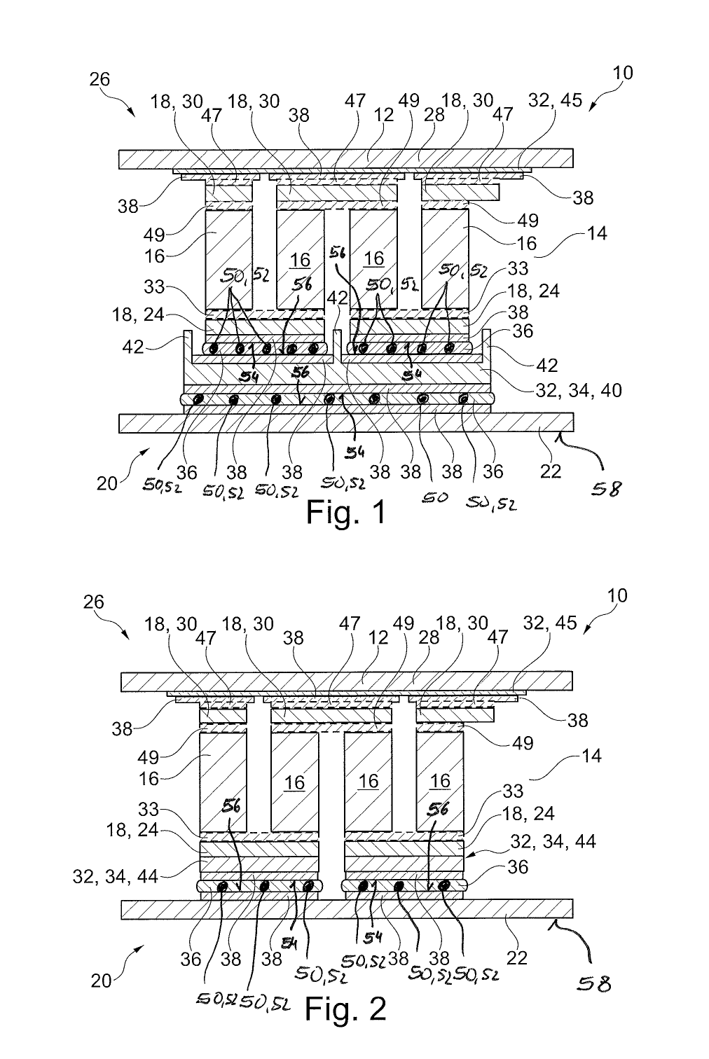

A second embodiment of the thermoelectric module 10 shown in FIG. 2 differs from the first embodiment of the thermoelectric module 10 illustrated in FIG. 1 in that the first electrical insulating layer 34 is formed by a plurality of ceramic elements 44 and in that the first conductor bridges 24 are in each case formed by a metalized surface 38 on the ceramic elements 44 of the first electrical insulating layer 34.

The ceramic elements 44 of the first electrical insulating layer 34 are thus connected to the thermoelectric elements 16 in a mechanically fixed manner via the first conductor bridges 24. The metallic surfaces 38, which form the first conductor bridges 24, preferably have a thickness of between 150 μm and 300 μm. A sufficient conductivity can thus be attained.

The ceramic elements 44 in each case further have a second metalized surface 38, which are disposed on the side located opposite the first conductor bridges 24, thus the side of the ceramic elements 44 facing the first side wall 22. These metalized surfaces 38 serve for the improved wetting of liquid metal layers 36, which are disposed between the first electrical insulating layer 34 and the first side wall 22. Due to the fact that the first electrical insulating layer 34 is formed by means of a plurality of ceramic elements 44, the metalized surfaces 38 are interrupted, whereby the liquid metal layer 36 is interrupted as well and thus each ceramic element 44 is thermally connected to the first side wall 22 by means of a separate liquid metal layer 36.

Apart from that, the second embodiment of the thermoelectric module 10 illustrated in FIG. 1, with regard to setup and function, corresponds to the first embodiment of the thermoelectric module 10 illustrated in FIG. 1, to the above description of which reference is made in this respect.

A third embodiment of the thermoelectric module 10 illustrated in FIG. 3 differs from the first embodiment of the thermoelectric module 10 illustrated in FIG. 1 in that the first side wall 22 is embodied in a double-walled manner and in that a liquid metal layer 36 runs between an inner wall 46 and an outer wall 48 of the first side wall 22. The inner wall 46 and the outer wall 48 can in each case be provided with a metalized surface 38, in order to improve the wetting with the liquid metal layer 36.

On a side, which faces the first conductor bridges 24, the inner wall 46 has the first electrical insulating layer 34. The first electrical insulating layer 34 can for example be formed by annealing a dielectric. In the alternative or in addition thereto, the first electrical insulating layer 34 can also be formed by thermal spraying of a ceramic onto the inner wall 46. The first electrical insulating layer 34 can further also be formed by means of a ceramic body, which is soldered to the inner wall 46.

The first conductor bridges 24 are connected to the first electrical insulating layer 34. Such a connection 51 can for example be a solder connection with hard solder or active solder. As an alternative thereto, the first conductor bridges 24 can also be connected to the first electrical insulating layer 34 by means of silver sintering.

To improve the wetting of the first electrical insulating layer 34, the latter can be provided with a metalized surface 38. Apart from that, the third embodiment of the thermoelectric module 10 illustrated in FIG. 3 corresponds, with regard to setup and function, to the first embodiment of the thermoelectric module 10 illustrated in FIG. 1, to the above description of which reference is made in this respect.

A fourth embodiment of the thermoelectric module 10 illustrated in FIG. 4 differs from the first embodiment of the thermoelectric module 10 illustrated in FIG. 1 in that the first electrical insulating layer 34 is formed by a coating of the first conductor bridges 24. The first electrical insulating layer 34 is thus divided into a plurality of layer sections, each of which coat the first conductor bridges 24. The first electrical insulating layer 34 is thereby applied to the respective first conductor bridge 24 from a plurality of sides. Only the side, to which the first conductor brides 24 are connected by means of the thermoelectric elements 16, is not covered by the first electrical insulating layer 34. The first electrical insulating layer 34 can for example be formed by a dielectric, which is applied to the conductor bridges by means of immersion, spraying or printing. The first conductor bridges 24 can thereby be embodied in a cuboidal manner or in a cuboidal manner comprising rounded corners. In the alternative or in addition thereto, the first conductor bridges 24 can also be formed as convexly formed metal sheet, wherein one side of the conductor bridges, which is connected to the thermoelectric elements 16, is flat.

A liquid metal layer 36 is disposed between the first electrical insulating layer 34 and the first side wall 22 and forms a thermal contact between the first side wall 22 and the first conductor bridges 24. For a better wetting, the first electrical insulating layer 34 as well as the first side wall 22 can be provided with a metalized surface 38.

Apart from that, the embodiment of the thermoelectric module 10 illustrated in FIG. 4 corresponds, with regard to setup and function, to the first embodiment of the thermoelectric module illustrated in FIG. 1, to the above description of which reference is made in this respect.

1. A thermoelectric module, comprising:
a plurality of thermoelectric elements;
a first side wall connected to a plurality of first conductor bridges in a thermally conductive manner;
a second side wall connected to a plurality of second conductor bridges in a thermally conductive manner; and
at least one liquid metal layer disposed between the first conductor bridges and an outer side of the first side wall, the at least one liquid metal layer facing away from the first conductor bridges, and at least one spacer being arranged in the at least one liquid metal layer;
wherein the thermoelectric elements are electrically interconnected to the first and second conductor bridges; and
wherein the thermoelectric elements extend between the first and second conductor bridges.

2. The thermoelectric module according to claim 1, wherein the at least one spacer includes a plurality of spacer elements.

3. The thermoelectric module according to claim 1, wherein the at least one spacer element is a separate component from at least one of a respective one of the first conductor bridges and the first side wall.

4. The thermoelectric module according to claim 1, wherein the at least one spacer element is a rolling body.

5. The thermoelectric module according to claim 4, wherein the rolling body is cylindrical or spherical.

6. The thermoelectric module according to claim 1, wherein:
the at least one liquid metal layer is in contact with an inner boundary wall on a side facing a respective one of the first conductor bridges;
the at least one spacer element directly touches the inner boundary wall;
the at least one liquid metal layer is in contact with an outer boundary wall on a side facing the first side wall; and
the at least one spacer element directly touches the outer boundary wall.

7. The thermoelectric module according to claim 1, wherein one of:
the first side wall is assigned to a cold side of the thermoelectric module, and the second side wall is assigned to a warm side of the thermoelectric module; or
the first side wall is assigned to the warm side, and the second side wall is assigned to the cold side.

8. The thermoelectric module according to claim 1, wherein at least one of:
the thermoelectric module has a first electrical insulating layer disposed between the first conductor bridges and the first side wall;
the at least one liquid metal layer is disposed between the first conductor bridges and the first electrical insulating layer; and
the at least one liquid metal layer is disposed between the first electrical insulating layer and the first side wall.

9. The thermoelectric module according to claim 8, wherein:
the first electrical insulating layer is formed by a structured ceramic body; and
on a side facing the first conductor bridges, the structured ceramic body has webs, which separate areas assigned to individual ones of the first conductor bridges from one another.

10. The thermoelectric module according to claim 9, wherein one of:
the structured ceramic body has a plurality of metalized surfaces, wherein the metalized surfaces are interrupted by the webs on the side facing the first conductor bridges; or
the structured ceramic body has a cohesive metalized surface on a side facing the first side wall.

11. The thermoelectric module according to claim 8, wherein:
the first electrical insulating layer is formed by a plurality of ceramic elements;
the first side wall has a plurality of metalized surfaces;
each liquid metal layer abuts on a corresponding one of the metalized surfaces of the first side wall;
the ceramic elements have metalized surfaces on a side facing away from the first conductor bridges; and
each liquid metal layer abuts on a corresponding one of the metalized surfaces of the ceramic elements.

12. The thermoelectric module according to claim 1, wherein:
the first side wall is double-walled;
the first side wall has an inner wall, which faces the first conductor bridges, and an outer wall, which faces away from the first conductor bridges and has the outer side; and
one liquid metal layer is disposed between the inner wall and the outer wall.

13. The thermoelectric module according to claim 12, wherein the first electrical insulating layer is applied to a side of the inner wall.

14. The thermoelectric module according to claim 8, wherein:
the first electrical insulating layer is applied to the first conductor bridges;
the first side wall has a plurality of metalized surfaces;
each liquid metal layer abuts on a corresponding one of the metalized surfaces of the first side wall;
the first conductor bridges each has a metalized surface on the first electrical insulating layer; and
each liquid metal layer abuts on a metalized surface of the first electrical insulating layer.

15. The thermoelectric module according to claim 1, further comprising a module housing surrounding a module interior, wherein:
the thermoelectric elements are disposed in the module interior;
the first and second conductor bridges are disposed in the module interior;
the first side wall forms a first side of the module housing, which is provided for contacting a heat source or heat sink; and
the second side wall forms a second side of the module housing, which is provided for contacting a heat sink or heat source.

16. The thermoelectric module according to claim 1, wherein the at least one spacer element is a separate component from at least one of a respective one of the first conductor bridges and the first side wall.

17. The thermoelectric module according to claim 2, wherein the at least one spacer element is a rolling body.

18. The thermoelectric module according to claim 3, wherein the at least one spacer element is a rolling body.

19. The thermoelectric module according to claim 18, wherein the rolling body is cylindrical or spherical.

20. A thermoelectric module, comprising:
a plurality of thermoelectric elements;
a first side wall connected to a plurality of first conductor bridges in a thermally conductive manner;
a second side wall connected to a plurality of second conductor bridges in a thermally conductive manner;
at least one liquid metal layer disposed between the first conductor bridges and an outer side of the first side wall, the at least one liquid metal layer facing away from the first conductor bridges, and at least one spacer being arranged in the at least one liquid metal layer; and
a first electrical insulating layer disposed between the first conductor bridges and the first side wall;
wherein the thermoelectric elements are electrically interconnected to and extend between the first and second conductor bridges;
the at least one liquid metal layer is disposed between one of:
the first conductor bridges and the first electrical insulating layer; or
the first electrical insulating layer and the first side wall.
